(19) United States
(12) Patent Application Publication
(10) Pub. No.: US 2012/0228704 A1
(43) Pub. Date: Sep. 13, 2012

(54) High-Voltage MOSFET with High Breakdown Voltage and Low On-Resistance and Method of Manufacturing the Same

(76) Inventor: Dong-Hyuk Ju, Cupertino, CA (US)

(21) Appl. No.: 13/041,512

(22) Filed: Mar. 7, 2011

(51) Int. Cl. H01L 29/78; H01L 21/336

(52) U.S. Cl. 257/339; 438/286; 257/E29.256; 257/E21.417

(57) ABSTRACT

A high-voltage transistor is formed in a deep well of a first conductivity type that has been formed in a semiconductor substrate or epitaxial layer of a second conductivity type. A body region of the second conductivity type is formed in the deep well, into which a source region of the first conductivity type is formed. A drain region of the first conductivity type is formed in the deep well and separated from the body region by a drift region in the deep well. A gate dielectric layer is formed over the body region, and a first polysilicon layer formed over the gate dielectric layer embodies the gate of the transistor. The field plate dielectric layer is formed over the drift region after the gate has been formed. Finally, the field plate dielectric is covered by a second polysilicon layer having a field plate positioned over the field plate dielectric layer in the drift region.

### FIELD OF THE INVENTION

The present invention is directed at high-voltage metal-oxide-semiconductor field-effect transistors and methods of their manufacture.

### BACKGROUND OF THE INVENTION

High-voltage metal-oxide-semiconductor field-effect transistors (HV MOSFETs) are used in a wide variety of power integrated circuits (ICs). For example, they serve as high-voltage switches in high-voltage switching regulators and power management ICs. They are also used extensively in display driver ICs for modern flat panel displays. To handle the high voltages involved in these and other high-voltage applications, the HV MOSFETs must be designed to have a high breakdown voltage (BV). Further, in order to achieve high power efficiencies and realize small die sizes, the HV MOSFETs should also have low on-resistances (Ron). Unfortunately, manufacturing a HV MOSFET having both a high BV and low Ron is difficult to achieve.

FIG. 1 is a cross-sectional drawing of one type of HV MOSFET, known in the art as a laterally-diffused (LD) MOSFET or LDMOS transistor 100, designed to have a high BV. The LDMOS transistor 100 shown is an n-channel device formed in a deep n-well in a p-type substrate 102. A p-body 106 and shallow n-well 108 are formed in the deep n-well 104, and heavily-doped n+ source and drain regions 110 and 112 are formed in the p-body and shallow n-well 108, respectively. A heavily-doped p+ body contact region (i.e., back gate connection region) 114 is also formed in the p-body 106 and electrically shorted to the n+ source region 110. A thin gate oxide layer 116 extends over a channel region 118 in the p-body 106 and over a portion of a drift region 120 between the p-body 106 and the shallow n-well 108. Along the periphery of the LDMOS transistor 100, a thick field oxide (FOX) layer 122 is formed. The FOX layer 122 electrically isolates the LDMOS transistor 100 from other transistors and devices formed on the p-substrate 102. During manufacturing, the same processing steps used to fabricate the FOX layer 122 are used to form a field plate oxide 124 of the same thickness over the drift region 120. Finally, a polysilicon gate 126 is formed over the gate oxide layer 116. A portion of the polysilicon gate 126 extends over the field plate oxide 124 and is referred to in the art as the “field plate” 128.

The LDMOS transistor 100 achieves a high BV by incorporating the drift region 120, which is laterally disposed between the right-most edge of the channel region 118 and the n+ drain region 112. The drift region 120 serves as a structure over which a significant portion of the high-voltage power supply may be dropped, and in so doing increases the drain-source BV of the LDMOS transistor 100. The field plate 128 and underlying field plate oxide 124 help to further increase the BV by reducing electric field crowding in the vicinity of the channel region 118 of the LDMOS transistor 100. Using the field plate 128 to help increase the BV is beneficial, especially since it allows the BV of the LDMOS transistor 100 to be increased without having to accept a concomitant increase in Ron. However, because the field plate oxide 124 comprises the same layer as the FOX layer 122, the thickness of the field plate oxide 124 is set during processing and is not capable of being varied or controlled independent of the thickness of the FOX layer 122. This constraint limits the ability to precisely control the BV and achieve a desired combination of BV and Ron. Various approaches have been proposed to avoid this problem. Unfortunately, those other approaches are plagued with similar or related problems or involve fabrication processes that result in degraded transistor performance and/or reliability concerns.

### SUMMARY OF THE INVENTION

High-voltage (HV) transistors and method of their manufacture are disclosed. According to one embodiment of the invention, an exemplary HV transistor is formed in a deep well of a first conductivity type that has been formed in a semiconductor substrate or epitaxial layer of a second conductivity type. A body region of the second conductivity type is formed in the deep well, into which a source region of the first conductivity type is formed. A drain region of the first conductivity type is formed in the deep well and separated from the body region by a drift region in the deep well. A gate dielectric layer is formed over the body region, and a first polysilicon layer formed over the gate dielectric layer embodies the gate of the transistor. The field plate dielectric layer is formed over the drift region and, advantageously, after the gate has been formed. Delaying forming the field plate dielectric until after the gate has been formed allows the gate to be formed as soon as possible after the gate dielectric layer has been grown, thereby reducing the opportunity for the gate dielectric layer to be exposed to the environment and/or external contaminants. It also allows the gate to protect the underlying gate dielectric layer from being etched during the time the field plate dielectric layer is being formed. Finally, the field plate dielectric is covered by a second polysilicon layer having a field plate that is positioned over the field plate dielectric layer in the drift region. In one embodiment of the invention, an inter-poly dielectric is also deposited over the gate and field plate dielectric, prior to forming the second polysilicon layer. The inter-poly dielectric serves as an etch stop that prevents the gate from being etched as the second polysilicon layer is being formed.

According to one aspect of the invention, the field plate dielectric is formed independent of other dielectric-layer-forming processes, thereby providing flexibility in the type of dielectric material that may be used. In one embodiment of the invention, a high-k dielectric material (e.g., a dielectric material having a dielectric constant k greater than the dielectric constant of silicon dioxide) is used.

Forming the field plate dielectric layer independent of other dielectric-layer-forming processes not only provides flexibility in the type of material that may be used for the field plate dielectric, it also allows the thickness of the field plate dielectric layer to be controlled during processing, thereby providing an additional degree of freedom in optimizing the breakdown voltage of the HV transistor.

According to another aspect of the invention the field plate dielectric layer is formed not only after the gate has been formed but also after all significant thermal cycles have been performed, including, for example, the high-temperature anneal applied following the implantation of the source, drain and body contact regions of the transistor. Delaying forming the field plate dielectric until after all significant high-temperature thermal cycles have been performed is beneficial, particularly for field plate dielectric materials that may be susceptible to heat-induced electrical and/or mechanical damage.

Further details of the above-summarized HV transistor and its method of manufacture, as well as details of other embodiments of the HV transistor and their methods of manufacture, are described below with respect to the accompanying drawings, in which like reference numbers are used to indicate identical or functionally similar elements.

### BRIEF DESCRIPTION OF THE DRAWINGS

FIG. 1 is a cross-sectional drawing of a high-voltage (HV) transistor known in the prior art;

FIG. 2 is a cross-sectional drawing of a HV transistor, according to an embodiment of the present invention;

FIG. 3 is a flowchart of an exemplary fabrication process that may be used to fabricate the HV transistor in FIG. 2;

FIGS. 4A-N are cross-sectional drawings of the HV transistor in FIG. 2 at various stages in its manufacture;

FIG. 5 is a cross-sectional drawing of a prior art high-voltage (HV) transistor, according to another embodiment of the present invention;

FIG. 6 is a cross-sectional drawing of a prior art high-voltage (HV) transistor, according to another embodiment of the present invention;

FIG. 7 is a flowchart of an exemplary fabrication process that may be used fabricate the HV transistor in FIG. 6; and

FIG. 8 is a cross-sectional drawing of a prior art high-voltage (HV) transistor, according to another embodiment of the present invention.

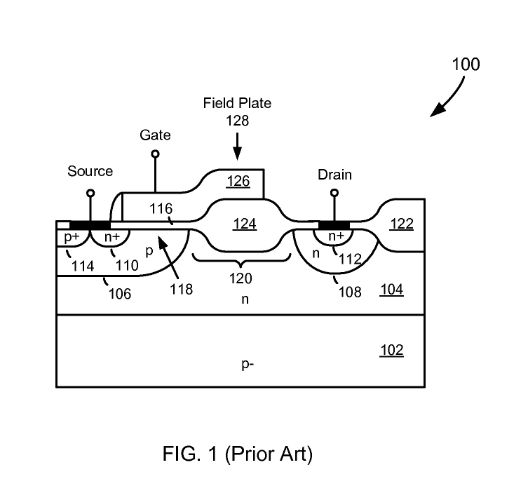

### DETAILED DESCRIPTION

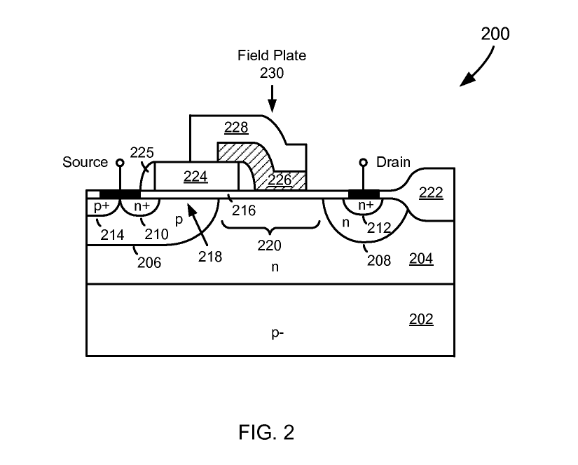

Referring to FIG. 2 there is shown a high-voltage (HV) transistor 200, according to an embodiment of the present invention. The HV transistor 200 is located in a deep n-well 204 that has been implanted and diffused in a p-type substrate 202 or, alternatively into a p-type epitaxial layer formed on a substrate. A p-body region 206 in the deep n-well 204 includes heavily-doped n+ source and p+ body contact regions 210 and 214 that are in direct electrical contact with one another. A shallow n-well 208, also formed in the deep n-well 204, contains a heavily-doped n+ drain region 212. The shallow n-well 208, which is included to reduce the on resistance (Ron) of the HV transistor 200, is separated from the p-body region 206 by a drift region 220 and has a doping concentration intermediate that of the deep n-well 204 and the n+ drain region 212. A gate dielectric layer 216 comprising silicon dioxide (SiO₂) or a high-k dielectric material (“high-k” meaning a high dielectric constant greater than the dielectric constant (3.9) of silicon dioxide (SiO₂)) extends from the n+ source region 210 over a channel region 218 in the p-body region 206 and drift region 220 in the deep n-well 204, and to the n+ drain region 212. The gate dielectric layer 216 includes openings through which metal contacts (not shown) to the n+ source and drain regions 210 and 212 and p+ body contact region 214 are formed. The gate of the HV transistor 200 comprises a conductive polysilicon region 224 (i.e., “gate poly” 224) disposed over the gate dielectric layer 216 in the channel region 218 in the p-body region 206. Sidewall spacers 225 adjacent the sidewalls of the gate poly 224 serve to self-align the n+ source region 210 to the gate poly 224 during fabrication. A field plate dielectric 226 comprising silicon nitride (Si₃N₄), halfnium dioxide (HfO₂), halfnium silicate (HfSiO₂), or other high-k material is formed over the gate dielectric layer 216 in the drift region 220 and includes a field plate dielectric extension that extends part way over an upper surface of the gate poly 224. The field plate dielectric 226 comprises a type of dielectric material and has dimensions that are selected and controlled during the fabrication process to: reduce field crowding near the channel region 218/drift region 220 boundary, optimize the BV of the HV transistor 200, and/or realize a desired combination of BV and Ron. It should be mentioned that while a high-k, non-SiO₂ material is preferred, the field plate dielectric 226 may alternatively be formed from SiO₂. Finally, a second poly layer 228 covers a portion of the gate poly 224 and the field plate dielectric 226. The portion of the second poly layer 228 that extends over the field plate dielectric 226 serves as the field plate 230 for the HV transistor 200.

It should be noted that the dimensions of the various regions of the HV transistor 200 in FIG. 2 and other drawings of this disclosure, including the thicknesses of its various layers, depth and lateral reach of its doped regions, and relative lengths of its channel and drift regions 218 and 220 are not necessarily drawn to scale. In some cases, layer thicknesses, junction depths, lengths and other dimensions are exaggerated so as to best illustrate the structural features and/or functional aspects of the HV transistor 200.

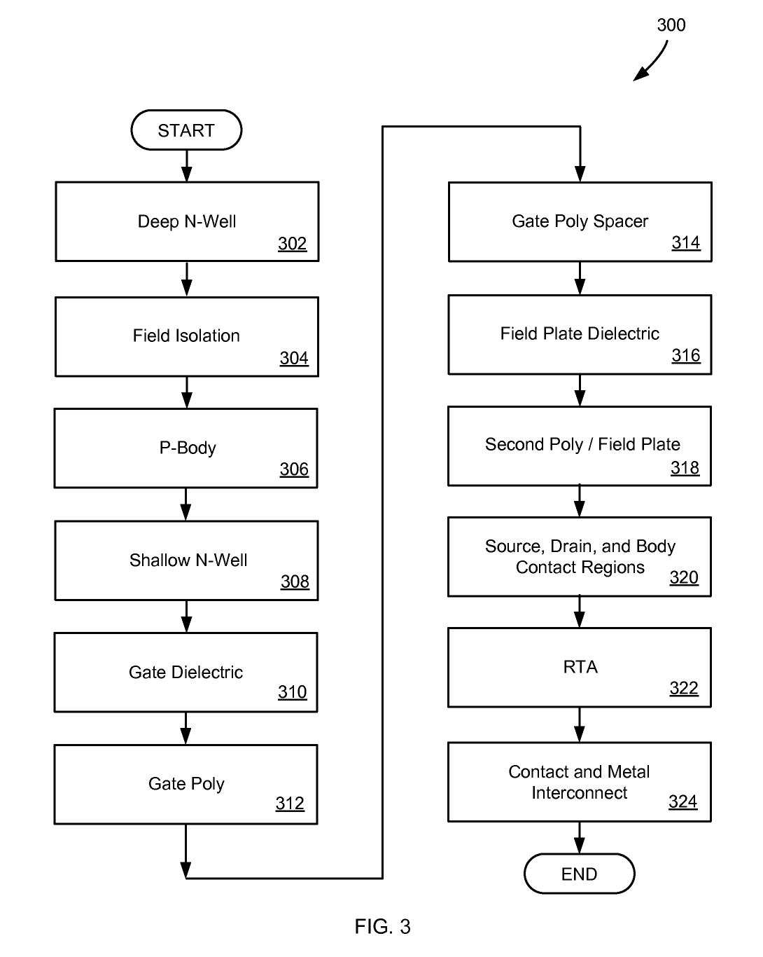

FIG. 3 is a flowchart showing salient steps of an exemplary fabrication process 300 that may be used to fabricate the HV transistor 200 in FIG. 2. Routine steps known to be employed by those of ordinary skill in the art are not shown and described, so as to avoid unnecessary obfuscation. Most of the routine steps are identical or substantially similar to steps and operations employed in standard complementary MOS (CMOS) semiconductor manufacturing processes, details of which may be found in “CMOS Circuit Design, Layout, and Simulation,” by R. Jacob Baker, Revised Second Edition, IEEE Press, John Wiley & Sons (2008), which is hereby incorporated by reference in its entirety and for all purposes. Further, whereas the salient steps of the fabrication process 300 are shown, depending on the circumstances some of the salient steps need not necessarily be performed, or, unless explicitly stated that one step precedes or follows another, may be performed in a different order than shown and described.

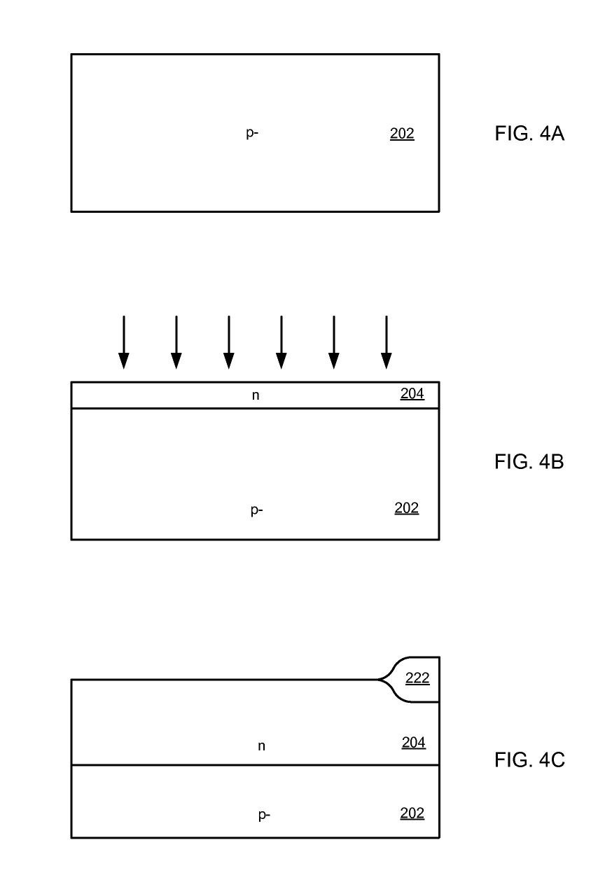

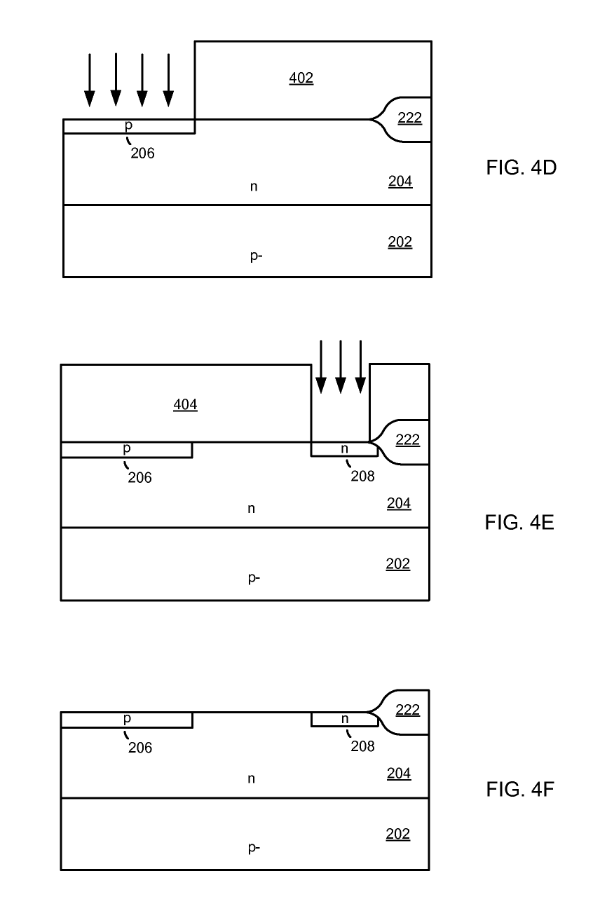

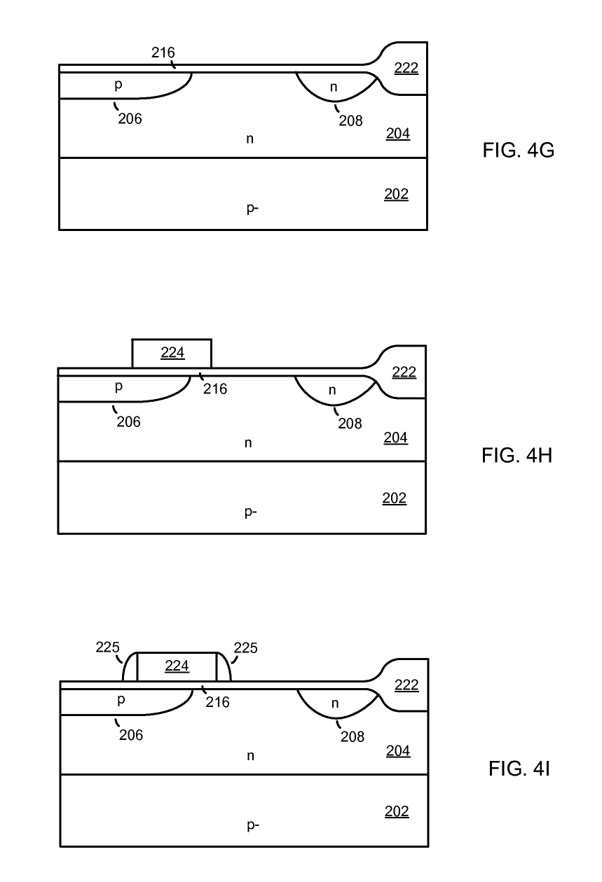

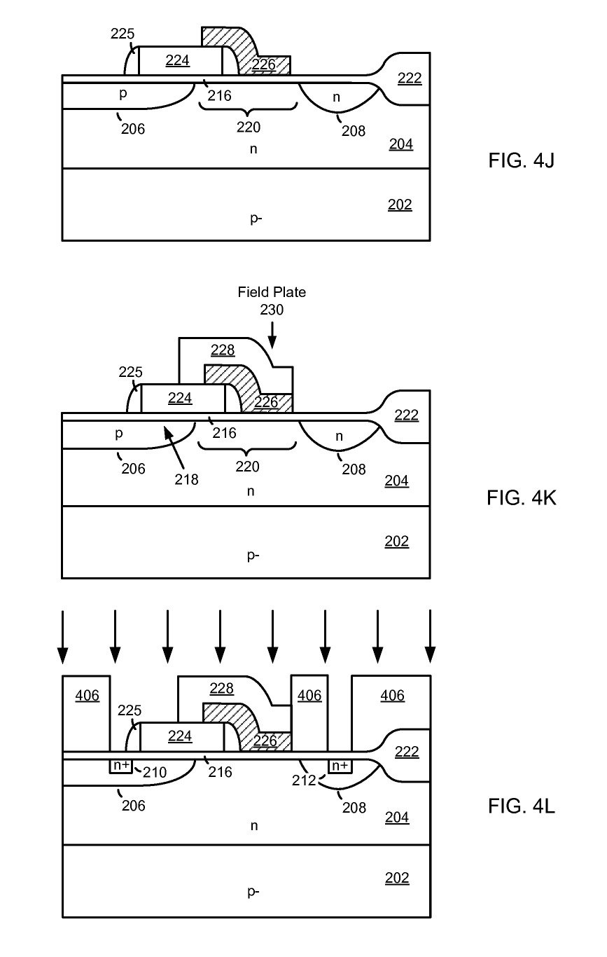

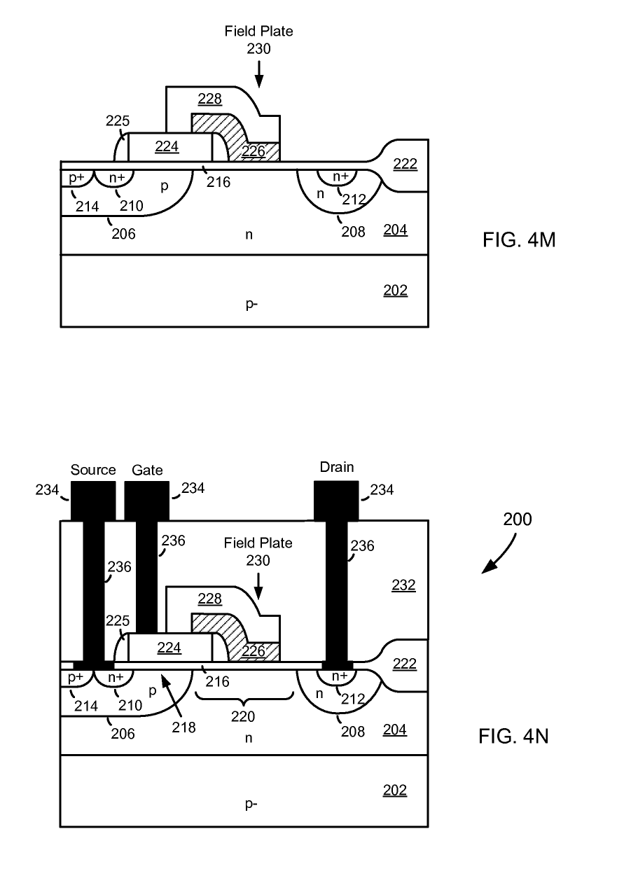

FIGS. 4A-M are cross-sectional drawings of the HV transistor 200 at various stages in the exemplary fabrication process 300 outlined in FIG. 3. They will be referred to in the description of the fabrication process 300 below. It should be noted that while only a single HV transistor 200 is shown as being fabricated by the fabrication process 300, those of ordinary skill in the art will understand and appreciate that a plurality of transistors, including possibly a plurality of low-voltage transistors depending on the type of integrated circuit being formed, would be typically formed simultaneously across a semiconductor wafer serving as the substrate 202. Further, whereas the exemplary fabrication methods of the present invention illustrate the fabrication of an n-channel MOSFETs (i.e., “NMOS” transistors), those of ordinary skill in the art will understand that the fabrication process 300 could also include processing steps for forming complementary MOSFETs, i.e., p-channel MOSFETs (PMOS transistors) having doped regions with conductivity types opposite that of the NMOS transistors. However, because the PMOS transistors would be fabricated in substantially the same manner as the NMOS transistors—the primary difference being simply the reversal in conductivity types of the various doped regions—only the fabrication of the NMOS transistors is shown and described.

The first task in the fabrication process 300 is forming the p-body 206/deep n-well 204 HV junction. This task involves several steps, including: forming the n-type deep n-well 204 in the p-substrate 202 (step 302); forming a field isolation region along or around the periphery of the deep n-well implant (step 304); and forming the p-body 206 and shallow n-well 208 regions (steps 306 and 308). These steps are discussed in more detail below, in reference to the cross-sectional drawings in FIGS. 4A-F.

In preparation of forming the deep n-well 204, a p-substrate 202 (or, alternatively, a substrate with a p-type epitaxial layer formed thereon) is first provided, as illustrated in FIG. 4A. Areas on the upper surface of the p-substrate 202 into which the n-type dopants for the deep n-well 204 are to be introduced are then delineated using a mask formed over the p-substrate 202. As will be understood by those of ordinary skill in the art, the mask and its pattern are formed by performing a photolithographic process that includes: coating the upper surface of the p-substrate 202 with a photosensitive polymer known as a photoresist (or “resist” for short); projecting ultraviolet (UV) light through a mask or reticle (not shown) onto the surface of the resist to define a pattern of areas on the p-substrate 202 into which n-type dopants for the deep n-well 204 are to be introduced; and developing the resist using an alkaline solution known as a developer so that those portions of the resist that were exposed and depolymerized by the UV light can be dissolved and removed. The resist layer that remains after removing the developed portion of the resist is baked, leaving a hardened resist mask with openings to the surface of the p-substrate 202 into which the deep n-well implant may be performed.

As illustrated in FIG. 4B, phosphorous (Ph) ions (n-type dopants or “donors”) are implanted into the p-substrate 202 by an ion implanter through the openings in the hardened resist mask (mask not shown). Other areas of the p-substrate 202 covered by the resist mask block the implant. In one embodiment of the invention, the ion implanter is configured to implant the Ph ions at an energy of between about 100 keV and 300 keV and dose of between about 10¹²-10¹³ cm⁻². Following subsequent thermal treatment cycles in the fabrication process 300, the final average volumetric dopant density of the deep n-well 204 will be within the range of approximately 10¹⁵-10¹⁶ cm ⁻³.

Following the deep n-well implant, the deep n-well resist mask is removed in preparation of forming the field isolation in step 304. The field isolation step 304 involves growing a FOX layer 222 by a thermal oxidation process, e.g., a conventional local oxidation of silicon (LOCOS) process. The LOCOS process is a high-temperature (<1000° C.) process which, in addition to forming the FOX layer 222, anneals the surface of the p-substrate 202 that was exposed to the deep n-well implant and activates and drives in (i.e., diffuses) the dopants from the deep n-well implant to a final junction depth of between about 3-5 micrometers (i.e., “microns”). It should be mentioned that whereas a LOCOS process is used to form a FOX layer 222 for field isolation purposes, a shallow trench isolation (STI) process may be alternatively employed for field isolation purposes, as will be appreciated and understood by those of ordinary skill in the art.

Following forming the FOX layer 222, p-body and shallow n-well implants are performed in steps 306 and 308. Each of these implants is preceded by formation of a patterned resist mask having openings defining the implant regions, using photolithographic processes similar to described above in forming the resist mask for the deep n-well implant. FIG. 4D is a cross-sectional drawing showing how a patterned resist mask 402 is used during the p-body implant. The dopants for the p-body implant comprise p-type dopants (i.e., “acceptors”) having a conductivity type opposite that of the n-type deep n-well 204. In one embodiment boron (B) ions are used for the p-type dopants. The B ions are implanted through an opening in the resist/mask 402 into the surface of the p-substrate 202 defining the p-body region 206, and areas of the p-substrate 202 covered by the resist mask 402 are prevented from being implanted. In one embodiment of the invention, the B ions are implanted into the p-substrate 202 at an energy of between about 50 and 100 keV and dose of approximately 10¹³ cm⁻².

Similarly, a patterned resist mask 404 is used during the shallow n-well implant, as illustrated in FIG. 4E. The n-type dopants for the shallow n-well 208 implant comprise Ph ions, which are implanted through openings in the resist mask 404 at an energy of between about 100 and 150 keV and dose of approximately 10¹³ cm⁻².

FIG. 4F is a cross-sectional drawing showing the partially completed transistor structure, including the p-body 206 and shallow n-well 208, following the p-body and shallow n-well implants. Subsequent thermal cycling is applied to activate and drive in the dopants to their final depths to complete formation of the p-body 206/deep n-well 204 HV junction, resulting in an average volumetric dopant density in both regions of about 10¹⁶ to 10¹⁷ cm⁻³ and junction depths of between about 1 and 3 microns.

The next step 310 in the fabrication process 300 involves forming the gate dielectric layer 216. In one embodiment of the invention the gate dielectric layer 216 comprises SiO₂, grown in accordance with a thermal oxidation process to a thickness of between about 100 and 1,000 Å. During the thermal oxidation process, dopants for the p-body 206 and shallow n-well 208 are partially diffused to intermediate, but not yet their final junction depths. The partially completed transistor structure following formation of the gate dielectric layer 216 is shown in FIG. 4G.

It should be mentioned that, although in the exemplary embodiment described here SiO₂ is used for the gate dielectric layer 216, in an alternative embodiment a non-SiO₂ material (for example, a high-k dielectric) is used and formed by a chemical vapor deposition (CVD) or physical vapor deposition (PVD) process. In yet another embodiment, a multi-layered gate dielectric layer comprising a high-k dielectric layer and thin SiO₂ buffer layer is used for the gate dielectric layer 216. The resulting high-k dielectric stack affords the ability to increase the drive current capability of the HV transistor 200 beyond that which can be realized by using only a single-layer SiO₂ gate dielectric layer 216.

After the gate dielectric layer 216 has been formed, in step 312 the gate poly 224 is formed over the gate dielectric layer 216, as shown in FIG. 4H. Forming the gate poly 224 involves depositing a 1,000 to 4,000 Å layer of polysilicon and patterning and etching the deposited polysilicon to define the lateral dimensions of the gate poly 224. Note that the gate poly 224 is made conductive by introducing n-type dopants into the poly gate 224 during subsequent n+ source and drain region implants described below. Alternatively, it may be doped to its desired conductivity level immediately following the polysilicon deposition by, for example, introducing Ph dopants from a phosphorous oxychloride (POCl₃) source into the polysilicon.

After the gate poly 224 has been formed, in step 314 sidewall spacers 225, comprising for example Si₃N₄, are formed adjacent the sidewalls of the gate poly 224 using an anisotropic etch, resulting in the structure illustrated in FIG. 4I. Although not shown in the drawings, it should be mentioned that an n-type lightly-doped drain (LDD) implant, self-aligned to the source-side edge of the gate poly 224, may also be performed prior to forming the sidewall spacers 225. The resulting LDD region serves to suppress hot carrier injection and ensures proper overlap of the n+ source region 210 (formed later in the fabrication process 300) with the gate poly 224.

Next, in step 316 the field plate dielectric 226 is deposited and patterned. The field plate dielectric 226 comprises silicon nitride (Si₃N₄), a halihium-based dielectric such as halfnium dioxide (HfO₂) or halfnium silicate (HfSiO₂), or other high-k dielectric material. The partially completed transistor structure following completion of step 316 is shown in FIG. 4J, where it is seen that the resulting field plate dielectric 226 is positioned over the drift region 220 and includes a field plate dielectric extension that extends over a portion of the gate poly 224. Note that the thickness of the field plate dielectric 226 is determined based on the dielectric constant of material used and the BV requirement of the HV transistor 200, which is set by design. For example, depending on the type of material used and BV design criterion, the field plate dielectric 226 may be made to have a thickness of anywhere within the range of about 100 to 5,000 Å.

Forming the field plate dielectric 226 independent of other manufacturing steps, and after the gate poly 224 has been formed, offers a number of advantages. First, forming the field plate dielectric 226 independent of other steps in the fabrication process 300 provides flexibility in selecting the type of material for the field plate dielectric 226 and controlling its thickness. Further, by forming the field plate dielectric 226 after the gate poly 224 has been formed, the gate poly 224 can be formed over the gate dielectric layer 216 immediately after the gate dielectric 216 has been deposited, thereby preventing the gate dielectric layer 216 from unnecessary or prolonged exposure to the environment and/or external contaminants that could otherwise cause surface defects and other material-related degradations. Forming the field plate dielectric 226 after the gate poly 224 has been formed also allows the gate poly 224 to protect the underlying gate dielectric layer 216 from being etched and/or damaged during the time the field plate dielectric layer 226 is being formed.

It should be mentioned that the field plate dielectric 226 is not formed this early in the fabrication process 300 in all embodiments of the invention. For example, in some embodiments of the invention, the field plate dielectric 226 is formed after all significant high-temperature thermal cycles have been performed, including, for example, the rapid thermal anneal performed following the n+ source/drain and p+ body contact implants (discussed below). Delaying forming the field plate dielectric 226 until after all significant high-temperature thermal cycles have been performed can be beneficial, particularly for field plate dielectric materials that are susceptible to heat-induced electrical and/or mechanical damage. For the purpose of illustrating the exemplary fabrication process 300, however, it will be assumed in the description that follows that the field plate dielectric 226 is formed after formation of the gate poly 224 but prior to forming the second poly layer 228 (discussed next) and prior to the n+ source/drain and p+ body contact implants (discuss later), i.e., in the order shown in FIG. 3.

After the field plate dielectric 226 has been deposited and patterned, in step 318 a second poly layer 228 is formed over the field plate dielectric 226 and a portion of the gate poly 224 using photolithography and etching operations. Like the gate poly 224, the second poly layer 228 is doped in subsequent steps (for example, during the n+ source/drain and p+ body contact implants discussed below), to make it conductive. The resulting partially completed transistor structure following depositing and patterning the second poly layer 228 is illustrated in FIG. 4K. Note that the portion of the second poly layer 228 that overlies the field plate dielectric 226 serves as the field plate 230 for the HV transistor 200.

Next, in step 320 n-type dopants are implanted through openings in a patterned source/drain resist mask 406 to form heavily-doped n+ source and n+ drain regions 210 and 212. The previously-formed sidewall spacers 225 serve to self-align the n+ source region 210 to the gate poly 224 edge. As alluded to above, the n-type dopants may also be implanted into the gate poly 224 and second poly layer 228 at this time, to render them conductive. A similar masking and implantation operation is performed to form the p+ body contact region 214, except that a p-type dopant is implanted. In one embodiment of the invention, arsenic (As) ions are used as the dopant source for the n+ source and drain region implants, and B or BF₂ ions are used as the dopant source for the p+ body contact region implant. In one embodiment of the invention, both implants are performed at an energy of between about 40 and 100 keV and dose of between about 10¹⁵-10¹⁶ cm⁻².

Following the n+ source/drain and p+ body contact region implants, in step 322 the transistor structure is exposed to a rapid thermal anneal (RTA). The RTA activates the dopants of the various doped regions, anneals silicon surfaces, and drives the various p-n junctions to their final depths. The RTA is performed at a temperature between about 900 and 1100° C. for a duration of between about 10 and 100 seconds, functioning specifically to drive the deep n-well 204 to a depth of between about 3-5 microns; the p-body 206/deep n-well 204 junction to a depth of between about 1-3 microns; and the n+ source/drain and p+ body contact regions 210, 212 and 214 to junction depths of between about 0.2 and 0.4 microns. FIG. 4M shows the transistor structure following the RTA.

The final major step in the fabrication process 300 is step 324. In this step the gate dielectric layer 216 and inter-layer dielectric layers (e.g., ILD layer 232) are selectively etched to produce openings (i.e., contact holes), which are subsequently filled with metal contact plugs 236 (e.g., tungsten), to create ohmic contacts with the underlying gate poly 224, n+ source and drain 210 and 212, and p+ body contact regions 214. After the contact plugs 236 have been formed, a metal layer 234 (e.g., aluminum or copper) of thickness between about 3,000 Å and 8,000 Å is deposited and patterned using standard photolithography and metal etching operations. The processing steps used to form the ILD layer 232, contact plugs 236, and metal layer 234 are well known in the art so are not described in detail here. FIG. 4N is a cross-sectional drawing of the HV transistor 200 following step 324.

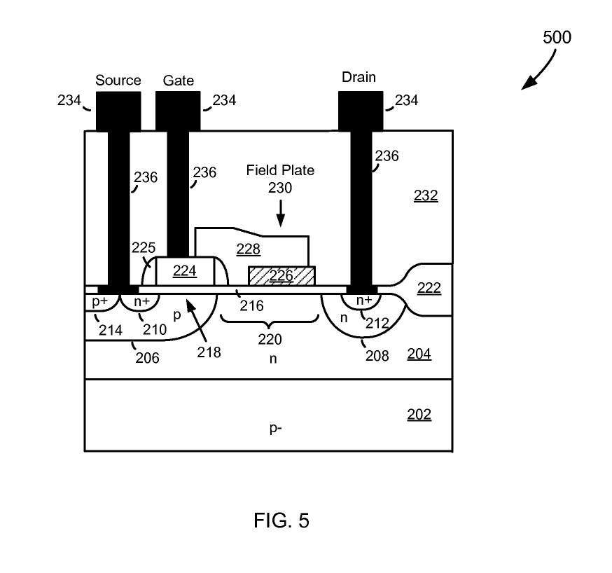

FIG. 5 is a cross-sectional drawing of a HV transistor 500, according to another embodiment of the invention. The HV transistor 500 is manufactured according to a fabrication process similar to the fabrication process 300 in FIG. 3, except that the field plate dielectric 226 is deposited and patterned so that it is uniplanar, i.e., so that it does not have an extension extending over the gate poly 224.

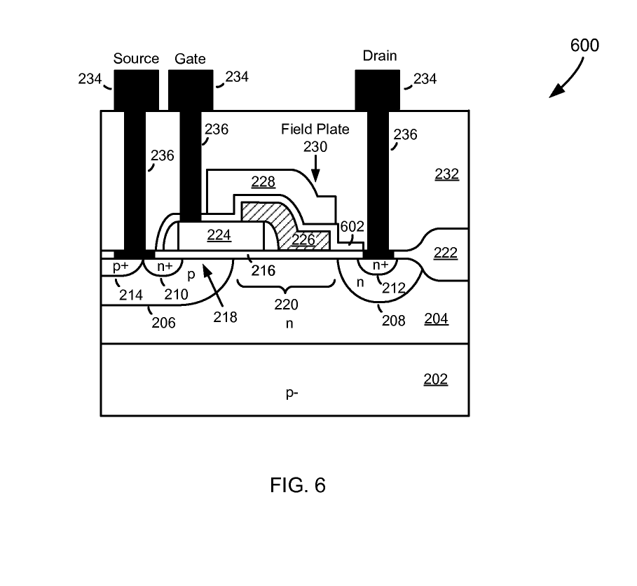

FIG. 6 is a cross-sectional drawing of a HV transistor 600, according to another embodiment of the invention. The HV transistor 600 is similar to the HV transistor 200 in FIG. 2, except that the HV transistor 600 includes an inter-poly dielectric layer 602 disposed between the gate poly 224 and field plate dielectric 226 and the second poly layer 228. The inter-poly dielectric layer 602 serves as an etch stop that protects the gate poly 224 from being etched during the time the second poly layer 228 is being etched. It is deposited to have a final thickness of between about 100 and 500 Å. It should be noted that, although the second poly layer 228 is not in direct contact with the gate poly 224, it nevertheless functions effectively as a field plate 230 for the HV transistor 600. This is because the voltage difference between the gate poly 224 and drain of the HV transistor 600 is divided between a first capacitor formed by the gate poly 224 and second poly layer 228 and a second capacitor formed by the second poly 228 and drain under the field plate dielectric 226, with the majority of the voltage being dropped across the latter.

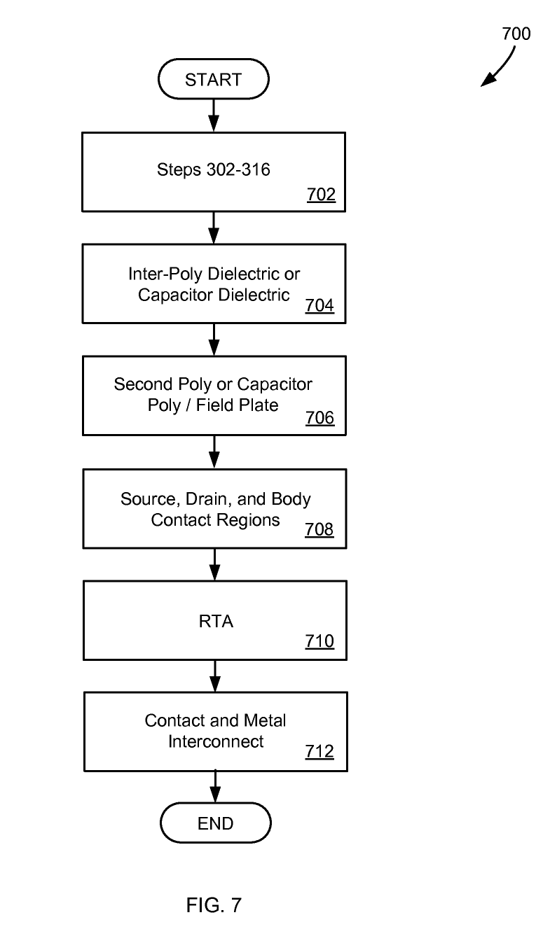

FIG. 7 is a flowchart showing salient steps of an exemplary fabrication process 700 that may be used to fabricate the HV transistor 600 in FIG. 6. Steps substantially similar to steps 302-316 of the fabrication process 300 are first performed in step 702. Then, in step 704 the inter-poly dielectric 602 is deposited, and the second poly layer 228 is deposited and patterned in step 706. According to one embodiment of the invention, the inter-poly dielectric layer 602 comprises a single layer dielectric such as SiO₂ or high-k dielectric. In another embodiment it comprises a multi-layer dielectric such as, for example, an oxide-nitride-oxide (or “ONO”) multi-layer dielectric or an SiO₂/high-k dielectric stack. In yet another embodiment, the inter-poly dielectric layer 602 comprises a dielectric formed from steps borrowed from a poly-to-poly, poly-insulator-poly (PIP), or other process used to fabricate capacitors for the integrated circuit in which the HV transistor 600 is fabricated. According to this embodiment of the invention, the second poly 228 and field plate 230 may also be formed from steps borrowed from the poly-to-poly or PIP capacitor process, or, alternatively, from steps borrowed from a poly-resistor-forming process. Poly-to-poly, PIP, and other capacitor-forming and resistor-forming processes are often included as supplementary steps in standard HV CMOS fabrication processes. Exploiting these readily-available processes to form the inter-poly dielectric layer 602 and/or second poly layer 228 is beneficial since it limits the number of nonstandard processing steps needed to fabricate the HV transistor 600.

After the second poly layer 228 has been deposited and patterned, in step 708 the n+ source/drain and p+ body contact region implants are performed (similar to as in step 320 of the exemplary fabrication process 300 described above), and in step 710 an RTA process is performed to drive the dopants from the n+ source/drain and p+ body contact region implants and the dopants from prior implants to their final depths. Finally, in step 712 metal contact plugs 236 for ohmic contact to the gate poly 224, n+ source and drain regions 210 and 212, and p+ body contact region 214 are formed (similar to as in step 324 of the exemplary fabrication process 300), yielding the HV transistor 600 in FIG. 6.

In the HV transistor 600 shown and described above in reference to FIG. 6, the gate poly 224 and second poly layer 228 are not in direct contact, so the second poly layer 228 is left floating during transistor operation. In some circumstances, however, it may be desirable for the two layers to be in direct contact. This can be accomplished by performing an extra photo-masking and etch step so that a portion of the upper surface of the gate poly 224 is exposed prior to and during depositing the second poly layer 228. In an alternative embodiment, the second poly layer 228 and gate poly 224 are left to remain electrically isolated but a contact hole is formed through the ILD layer 232 to the second poly layer 228. The contact hole is formed and filled with metal, for example at the same time the contact holes for the gate, source, drain and body contact region metal plugs 236 are formed and filled with metal. The metal-filled contact hole provides the ability to bias the second poly layer 228 during transistor operation, thereby providing an additional mechanism by which the BV of the HV transistor 600 may be controlled and optimized.

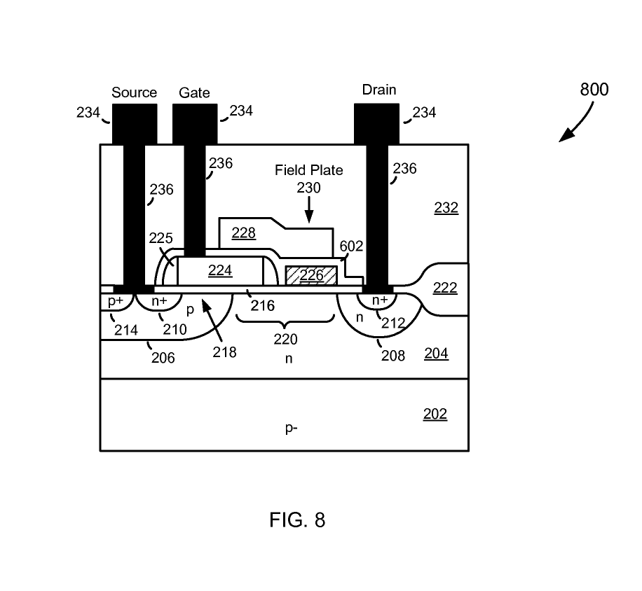

FIG. 8 is a cross-sectional drawing of a HV transistor 800, according to another embodiment of the invention. The HV transistor 800 is manufactured according to a fabrication process similar to the fabrication process 700 in FIG. 7, except the field plate dielectric 226 is patterned and etched so that it is uniplanar and does not include an extension over the gate poly 224.

While various embodiments of the present invention have been described, it should be understood that they have been presented by way of example, and not limitation. It will be apparent to persons skilled in the relevant art that various changes in form and detail may be made therein without departing from the spirit and scope of the invention. The scope of the invention should, therefore, be determined not with reference to the above description, but instead by reference to the appended claims, along with the full scope of equivalents to which such claims are entitled.

What is claimed is:

1. A high-voltage (HV) transistor, comprising:
a well of a first conductivity type in a semiconductor substrate or epitaxial layer of a second conductivity type;
a body region of the second conductivity type in said well;
a source region of the first conductivity type in said body region;
a drain region of the first conductivity type in said well and separated from said body region by a drift region in said well;
a gate dielectric layer extending from said source region and over a channel region in the body region;
a first polysilicon layer over said gate dielectric layer configured to serve as a gate;
a field plate dielectric over said drift region; and
a second polysilicon layer having a field plate positioned over said field plate dielectric,
wherein said field plate dielectric comprises a material selected and formed to have a thickness that optimizes the breakdown voltage of the HV transistor or realizes a desired combination of breakdown voltage and on-resistance.

2. The HV transistor of claim 1 wherein said field plate dielectric comprises a dielectric material having a dielectric constant greater than the dielectric constant of silicon dioxide.

3. The HV transistor of claim 1 wherein said field plate dielectric comprises silicon dioxide.

4. The HV transistor of claim 1 wherein said second polysilicon layer is configured to cover all or portions of said field plate dielectric and first polysilicon layer.

5. The HV transistor of claim 1 wherein said field plate dielectric includes an extension that extends between said first and second polysilicon layers and over a portion of said first polysilicon layer.

6. The HV transistor of claim 1 wherein said field plate dielectric is uniplanar and not in physical contact with said first polysilicon layer.

7. The HV transistor of claim 1, further comprising an inter-poly dielectric layer over said first polysilicon layer and said field plate dielectric.

8. The HV transistor of claim 7 wherein said second poly layer is insulated from said first polysilicon layer by said inter-poly dielectric layer.

9. The HV transistor of claim 7 wherein said inter-poly dielectric layer comprises a single-layer dielectric.

10. The HV transistor of claim 9 wherein said single-layer dielectric comprises a material having a dielectric constant greater than the dielectric constant of silicon dioxide.

11. The HV transistor of claim 7 wherein said inter-poly dielectric layer comprises a multi-layered dielectric.

12. The HV transistor of claim 11 wherein said multi-layered dielectric comprises an oxide-nitride-oxide (ONO) multi-layer structure.

13. The HV transistor of claim 7 wherein said inter-poly dielectric layer has an opening so that said second polysilicon layer is in direct contact with said first polysilicon layer.

14. The HV transistor of claim 1, further comprising a metal contact electrically connected to said second polysilicon layer, said metal contact configured to be connected to a bias voltage.

15. A method of manufacturing a HV transistor, comprising:
forming source and drain regions in a semiconductor substrate or epitaxial layer, said source and drain regions separated by channel and drift regions;
forming a gate dielectric layer that extends from said source over said channel region;
forming a polysilicon gate over said gate dielectric layer and channel region;
after forming said polysilicon gate, forming a field plate dielectric over said drift region; and
forming a second polysilicon layer having a field plate positioned over said field plate dielectric.

16. The method of claim 15 wherein forming said field plate dielectric includes controlling the thickness of said field plate dielectric to optimize the breakdown voltage of the HV transistor or realize a desired combination of breakdown voltage and on-resistance.

17. The method of claim 15 wherein said field plate dielectric comprises a material having a dielectric constant greater than the dielectric constant of silicon dioxide.

18. The method of claim 15 wherein said field plate dielectric comprises silicon dioxide.

19. The method of claim 15 wherein forming said field plate dielectric includes forming a field-plate-dielectric extension that extends over a portion of said polysilicon gate.

20. The method of claim 15 wherein forming said field plate dielectric comprises forming said field plate dielectric so that it is separated from said polysilicon gate in a first dimension and does not overlap with said polysilicon gate in a second dimension.

21. The method of claim 15 wherein said field plate dielectric is formed after dopants of said source and drain regions have been implanted and thermally driven to their final junction depths.

22. The method of claim 15 wherein said field plate dielectric is formed after all significant thermal cycles used to form the HV transistor have been applied.

23. The method of claim 15, further comprising forming an inter-poly dielectric layer over said polysilicon gate and said field plate dielectric prior to forming said second polysilicon layer.

24. The method of claim 23 wherein said inter-poly dielectric layer is used as an etch stop for protecting said polysilicon gate from being etched during forming said second polysilicon layer.

25. The method of claim 23 wherein forming said inter-poly dielectric layer includes forming an opening through said inter-poly dielectric layer over said polysilicon gate, so that after forming said second polysilicon layer said polysilicon gate is in direct contact with said second polysilicon layer.

26. The method of claim 23 wherein said inter-poly dielectric layer comprises a single-layer dielectric.

27. The method of claim 26 wherein said single-layer dielectric comprises a material having a dielectric constant greater than the dielectric constant of silicon dioxide.

28. The method of claim 23 wherein said inter-poly dielectric layer comprises a multi-layered dielectric.

29. The method of claim 28 wherein said multi-layered inter-poly dielectric layer comprises an oxide-nitride-oxide (ONO) multi-layer structure.

30. The method of claim 23 wherein said inter-poly dielectric layer is formed from processing steps borrowed from processing steps used to fabricate capacitors and/or resistors.

31. The method of claim 30 wherein said second polysilicon layer is also formed from processing steps borrowed from processing steps used to fabricate capacitors and/or resistors.

32. The method of claim 15, further comprising forming a metal contact for said second polysilicon layer, said metal contact used to apply a bias voltage to said second polysilicon layer.

33. The method of claim 32 wherein the metal contact for said second polysilicon layer is electrically isolated from said polysilicon gate.
